(19) United States
(12) Patent Application Publication
(10) Pub. No.: US 2006/0138652 A1
(43) Pub. Date: Jun. 29, 2006

(54) Solder for device package

(75) Inventors: Tae-hoon Jang, Seoul (KR); Won-kyoung Choi, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRO-MECHANICS CO., LTD., Gyeonggi-do (KR)

(21) Appl. No.: 11/200,120

(22) Filed: Aug. 10, 2005

(30) Foreign Application Priority Data
Dec. 27, 2004 (KR) 10-2004-0112920

(51) Int. Cl. H01L 23/34

(52) U.S. Cl. 257/728

(57) ABSTRACT

A solder for device packaging including a plurality of cores, and a coating solder mixed with the cores. The cores are formed of a material having a higher thermal conductivity than the coating solder.

### CROSS-REFERENCE TO RELATED PATENT APPLICATIONS

This application claims the benefit of Korean Patent Application No. 10-2004-0112920, filed on Dec. 27, 2004, in the Korean Intellectual Property Office, the disclosure of which is incorporated herein in its entirety by reference.

### BACKGROUND OF THE DISCLOSURE

1. Field of the Disclosure

The present invention relates to a solder for device packaging, and more particularly, to a solder for high-temperature, high-power device packaging that can improve heat emission.

2. Description of the Related Art

To package a device, such as, a light emitting device (LED), a laser diode (LD), or the like, a solder is generally designed so that the device can be bonded to a submount at a temperature as low as possible. Accordingly, a conventional solder for device packaging has been generally formed of a eutectic alloy that can lower a melting temperature. Examples of the eutectic alloy include an alloy of gold (Au) and tin (Sn), an alloy of tin (Sn) and silver (Ag), etc. These alloys have low eutectic temperatures.

However, such a eutectic alloy has a bad influence upon emission of heat generated by the device because the eutectic alloy has low thermal conductivity. Hence, a new solder that can satisfy melting characteristic and thermal conductivity is required by a high-temperature, high-power device package that is being developed of late.

### SUMMARY OF THE DISCLOSURE

Embodiments of the present invention provide a solder for device packaging that can effectively emit heat generated from a device by having a high thermal conductivity.

In embodiments of the present invention, there may be provided a solder for device packaging, including: a plurality of cores; and a coating solder mixed with the cores. The cores may be formed of a material having a higher thermal conductivity than the coating solder.

The coating solder may be formed with a predetermined thickness on surfaces of the cores so that the cores may be coated with the coating solder.

The cores may be formed of a material having a thermal conductivity of 50 W/mK to 1000 W/mK. The cores may be formed of at least one material of palladium (Pd), chrome (Cr), aluminum nitride (AlN), aluminum (Al), copper (Cu), boron nitride (BN) and diamond.

The coating solder may be formed of at least one material selected from an alloy of gold (Au) and tin (Sn), an alloy of Sn and silver (Ag), an ally of lead (Pb) and Sn and Ag.

### BRIEF DESCRIPTION OF THE DRAWINGS

The above and other features and advantages of embodiments of the present invention will become more apparent by describing in detail exemplary embodiments thereof with reference to the attached drawings in which:

FIG. 1 is a perspective view of a solder for device packaging according to an embodiment of the present disclosure;

FIG. 2 is a cross-section of the solder of FIG. 1;

FIG. 3 is a cross-section of a unit structure of the solder of FIG. 1;

FIGS. 4A through 4F are simulation results showing profiles of internal temperatures of the solder for device packaging of FIG. 1 when a core has thermal conductivity of 50 W/mk, 100 W/mk, 200 W/mk, 315 W/mk, 400 W/mk and 500 W/mk, respectively;

FIG. 5 is a graph showing temperatures of a core, a coating solder, and a heat source versus the thermal conductivity of a core based on the profiles shown in FIGS. 4A through 4F;

FIG. 6 is a graph showing temperatures of a heat source depending on a size of a core; and

FIG. 7 is a graph showing thermal conductivities of the solder for device packaging of FIG. 1 depending on the size of the core.

### DETAILED DESCRIPTION OF EXEMPLARY EMBODIMENTS OF THE DISCLOSURE

In embodiments of the present disclosure, a solder for device packaging used to bond a device, such as, a light emitting device (LED), a laser diode (LD), or the like, to a submount may effectively emit heat generated from the device to the submount. The effective heat emission may be achieved by improving the thermal conductivity of the solder. To improve the thermal conductivity of the solder, the solder for device packaging may be formed of a hybrid of an existing solder material and a material having a high thermal conductivity.

More specifically, the solder for device packaging may be comprised of a plurality of cores made of a material having a high thermal conductivity and a coating solder combined with the cores. The cores may be coated with the coating solder having a predetermined thickness. The coating solder may be formed of a material having thermal conductivity lower than that of the cores. A solder for device packaging having a desired melting point, a desired bonding characteristic, and a desired thermal conductivity may be designed by selecting appropriate materials of the cores and the coating solder and adjusting the content of the cores and the content of the coating solder. The solder for device packaging according to the present invention may be used under the same conditions as those under which an existing solder is used.

When a solder for device packaging has a structure as described above, that is, is comprised of cores made of a material having a high thermal conductivity and a coating solder with which the cores are coated, most of the heat generated from a device to be packaged may be exhausted via the cores, thereby improving heat emission compared with a conventional solder. The coating solder improves the bonding characteristic and the melting characteristic, similar to the existing solder.

The coating solder may be formed of the material of an-existing solder. Accordingly, the coating solder may be formed of at least one material selected from the group consisting of an alloy of gold (Au) and tin (Sn), an alloy of Sn and silver (Ag), an ally of lead (Pb) and Sn, and Ag.

The cores may be formed of a material having higher thermal conductivity than a material of the coating solder. The material of the cores may have a thermal conductivity of about 50 to about 1000 W/mK.

Table 1 shows thermal conductivities of various materials.

TABLE

| | Thermal | | Thermal |
|---|---|---|---|
| | conductivity | | conductivity |
| Material | (W/mK) | Material | (W/mK) |
| Air | 0.026 | AlN | 170˜230 |
| Teflon | 0.25 | Al | 237.5 |
| Glass | 1.4 | Au | 315 |
| Graphite | 24 | Cu | 400 |
| GaAs | 46 | BN | 500 |
| Pd | 73 | Diamond | 500˜600 |
| | | (powder) | |
| Cr | 94 | Diamond | 1000 |

Referring to Table 1, the cores may be formed of a material of palladium (Pd), chrome (Cr), aluminium nitride (AlN), aluminium (Al), copper (Cu), boron nitride (BN) and diamond that have thermal conductivity of 50 W/mK or greater. The cores may be formed of a combination of these materials.

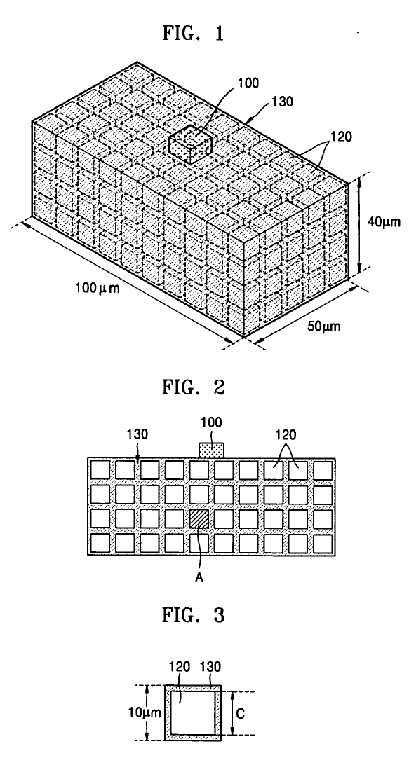

FIG. 1 is a perspective view of a solder for device packaging according to an embodiment of the present invention to which a heat source 100 is attached. FIG. 2 is a cross-section of the solder of FIG. 1. FIG. 3 is a cross-section of a unit structure of the solder of FIG. 1.

Referring to FIGS. 1 through 3, the solder for device packaging according to an embodiment of the present invention may be comprised of a plurality of cores 120 and a coating solder 130. The cores 120 have high thermal conductivity. The coating solder 130 with which each of the cores 120 may be coated. Although the cores 120 may be cubes for convenience of a simulation in the present embodiment, the cores 120 may have various shapes without limiting the present invention. In FIG. 3, reference character C denotes a size of a core when the coating solder 130 is 10 μm in size.

The heat source 100 may be attached to an upper surface of the solder for device packaging. The heat source 100 may be a device that needs to emit heat, such as, an LED, an LD, or the like.

A distribution of an internal temperature of the solder to which the heat source 100 has been attached was measured by a simulation. In the simulation, 0.5 W energy was applied to the heat source 100, and the temperature of a lower surface of the solder was kept constant as 25° C. The coating solder 130 was formed of a material having a thermal conductivity of 50 W/mK.

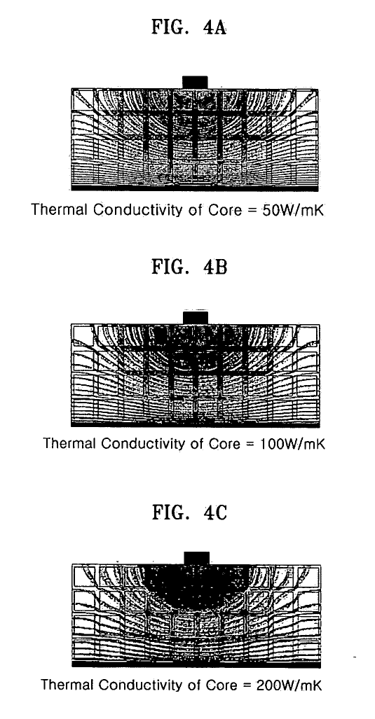

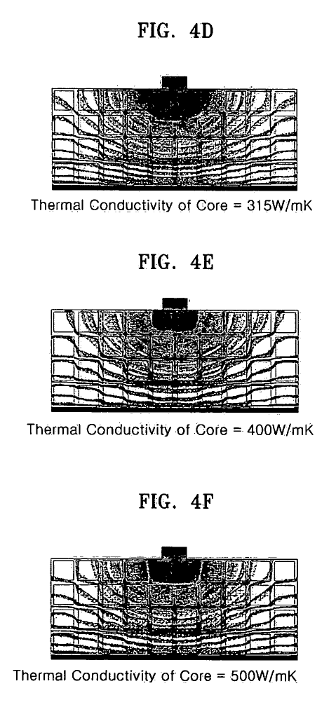

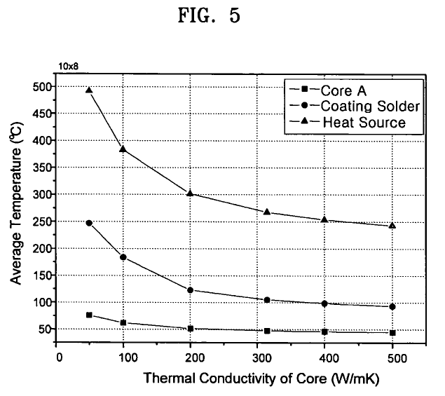

FIGS. 4A through 4F are simulation results showing profiles of internal temperatures of the solder for device packaging of FIG. 1 when a core has a thermal conductivity of 50 W/mk, 100 W/mk, 200 W/mk, 315 W/mk, 400 W/mk, and 500 W/mk, respectively. The simulation of FIGS. 4A through 4F was conducted when the coating solder 130 was 10 μm in size and the size C of each core is 8 μm. FIG. 5 is a graph showing temperatures of a core, a coating solder, and a heat source versus the thermal conductivity of a core based on the profiles shown in FIGS. 4A through 4F. In FIG. 5, core A denotes a portion of the core 120 that is indicated by A in FIG. 2. Referring to FIGS. 4A through 4F and 5, as the thermal conductivity of the core increases, the temperature of the heat source sharply decreases. Hence, as the thermal conductivity of the core increases, the solder for device packaging according to the present invention can effectively emit heat generated from the device to be packaged.

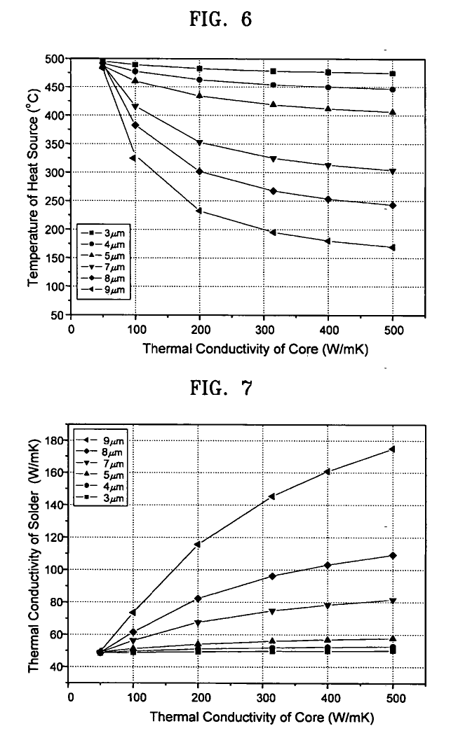

FIG. 6 is a graph showing temperatures of a heat source depending on a size of a core. FIG. 6 shows the temperatures of the heat source calculated with respect to the thermal conductivity of the core when a size of the coating solder was 10 μm with a variation of the size of the core to 3 μm, 4 μm, 5 μm, 7 μm, 8 μm and 9 μm. Referring to FIG. 6, as the size of the core increases, the temperature of the heat source sharply decreases. For example, when the thermal conductivity of the core was 400 W/mK, and the size of the core was 3 μm, the temperature of the heat source was 476.45° C. However, when the thermal conductivity of the core was still 400 W/mK, and the size of the core was changed to 8 μm, the temperature of the heat source was 253.56° C. Accordingly, as the content of the cores with respect to the coating is high, the solder for device packaging according to the present invention may effectively emit heat generated from a device to be packaged.

FIG. 7 is a graph showing thermal conductivities of the solder for device packaging of FIG. 1 depending on the size of the core. The thermal conductivities of the solder of FIG. 1 were calculated with respect to the thermal conductivity of the core 120 when a size of the coating solder was 10 μm with a variation of the size of the core to 3 μm, 4 μm, 5 μm, 7 μm, 8 μm and 9 μm. Referring to FIG. 7, as the size of the core 120 increases and the thermal conductivity of the core 120 increases, the thermal conductivity of the solder for device packaging increases. For example, when the core 120 was formed of Cu to a size of 9 μm, the thermal conductivity of the solder of FIG. 1 was 161 W/mK. When an existing solder formed of a Pb-Sn alloy having a thermal conductivity of 50 W/mK was used, the temperature of a heat source was 151.71° C. However, when the solder of FIG. 1 having a thermal conductivity of 161 W/mK was used, the temperature of the heat source was 138.56° C. Accordingly, the solder for device packaging of FIG. 1 can reduce the temperature of the heat source by about 9% compared with the existing solder.

As described above, a solder for device packaging according to the present disclosure can effectively emit heat generated from a device by including a plurality of cores formed of a material having a high thermal conductivity and a coating solder with which the cores are coated.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A solder for device packaging, comprising:
a plurality of cores; and
a coating solder mixed with the cores,
wherein the cores are formed of a material having a higher thermal conductivity than the coating solder.

2. The solder for device packaging of claim 1, wherein the coating solder has a predetermined thickness on surfaces of the cores so that the cores are coated with the coating solder.

3. The solder for device packaging of claim 1, wherein the cores are formed of a material having a thermal conductivity of 50 W/mK to 1000 W/mK.

4. The solder for device packaging of claim 3, wherein the cores are formed of at least one material selected from the group consisting of palladium (Pd), chrome (Cr), aluminum nitride (AlN), aluminum (Al), copper (Cu), boron nitride (BN), and diamond.

5. The solder for device packaging of claim 1, wherein the coating solder is formed of at least one material selected from the group consisting of an alloy of gold (Au) and tin (Sn), an alloy of Sn and silver (Ag), an ally of lead (Pb) and Sn, and Ag.

6. The solder for device packaging of claim 1, wherein the solder is used to bond a device that needs to emit heat to a submount.
